(19) United States
(12) Patent Application Publication
(10) Pub. No.: US 2024/0169132 A1
(43) Pub. Date: May 23, 2024

(54) METHOD AND SYSTEM FOR SELECTING ONE OR MORE CHARACTERISTICS FOR A NETLIST

(71) Applicants: Surya PENMETSA, Toronto (CA); Yingying FU, Toronto (CA); Yingxue ZHANG, Markham (CA); Yaochen HU, Montréal (CA)

(72) Inventors: Surya PENMETSA, Toronto (CA); Yingying FU, Toronto (CA); Yingxue ZHANG, Markham (CA); Yaochen HU, Montréal (CA)

(21) Appl. No.: 17/991,806

(22) Filed: Nov. 21, 2022

(51) Int. Cl. G06F 30/323; G06N 3/0464

(52) U.S. Cl. CPC G06F 30/323; G06N 3/0464

(57) ABSTRACT

Systems and methods for selecting one or more characteristics for a netlist. A graph data structure is generated, the components of the netlist and connections therebetween being represented by nodes and edges, respectively, in the graph data structure, wherein the edges between the nodes indicate types of the connections between the components. The graph data structure is processed to select one or more characteristics for the components.

### TECHNICAL FIELD

The present disclosure relates to hardware electronics design, and, in particular, to a method and system for selecting one or more characteristics for a netlist.

### BACKGROUND

In the design flow for analog circuits, the component sizes are to be determined after the construction of circuit schematics generally referred to as netlists. A netlist is a circuit schematic that consists of components, such as transistors, resistors, capacitors, etc., and the connections between them. The goal of transistor sizing is to find optimal component values to maximize some predefined metrics such as gain, bandwidth, and power. This is an important step that affects the physical layout of the components.

There are two main classes of methods: knowledge-based and optimization-based. In a knowledge-based approach, human designers analyze the circuit topology and derive equations (with many approximations) to determine a set of initial values for the parameters. A large number of simulations are performed around the initial values to search for the best possible configuration that meets pre-defined specifications. The main issue of this approach is that it requires the intensive labor of experienced designers. Besides, it is time-consuming due to the vast search space for parameters.

Alternatively, in an optimization-based approach, sometimes people use optimization-based methods which are automated algorithms that do not involve human intervention. They start with random guesses if the parameters and repeatedly refine these guesses. Some examples of such algorithms are black-box optimization such as Bayesian optimization, evolutionary search, etc. However, these approaches do not generalize across netlists. For example, learning on one netlist does not improve the performance on the design of other similar netlists. Every time a new netlist comes in (even if it is similar to an old design), there is a need to explore the optimal parameters from scratch.

More recently, people started to use reinforcement learning to tackle the above issue of finding the optimal parameters that can meet the target specification. To learn better representation for netlists, graph neural networks are adopted to encode the netlists. GCN-RL, as is disclosed in “Layout Symmetry Annotation for Analog Circuits with Graph Neural Networks”, ASPDAC '21: Proceedings of the 26th Asia and South Pacific Design Automation Conference, January 2021, Pages 152-157, (hereinafter referred to as “Layout Symmetry Annotation”) is the state-of-the-art model for analog circuit design. In this article, netlists are represented as homogeneous graphs and use a normal graph convolutional neural networks (GCN), as disclosed in “Semi-Supervised Classification with Graph Convolutional Networks”, arXiv: 1609.02907, to encode the netlists information, which is adopted as the state representation for the following Reinforcement Learning (RL) procedure, (ii) adopt a 1-time step reinforcement learning model to search for optimal parameters and apply standard RL algorithms such as DDPG, as disclosed in “Continuous control with deep reinforcement learning”, arXiv: 1509.02971, to train the model.

DDPG works as follows in the case of a 1-time step RL model. DDPG consists of three main components: (a) a replay buffer, (b) a critic, and (c) an actor. The replay buffer stores samples of all interactions of the agent with the environment. The critic learns to approximate the environment (estimate the rewards for some specific choices of parameters and the netlist) by using data samples from the replay buffer. The actor interacts with the critic to find the sizes of transistors that maximize the output of the critic.

The limitation of the approach in Layout Symmetry Annotation is the way that netlists are represented. This approach cannot differentiate some similar netlists since it ignores the heterogeneous edge type information and the component type information. For example, two similar netlists depicted in FIGS. 1A and 1B that include various components such as transistors, resistors, capacitors, etc. and how they are connected to each other, and which only differ in the transistor orientation are shown in FIGS. 1A and 1B. Both the netlists have the exact same graph representation, shown in FIG. 1C. Since both netlists have the same representation, the actor predicts the same rewards for both netlists, which in most cases, should be different.

### SUMMARY

The present disclosure describes systems and methods which provide one or more efficient techniques to select one or more characteristics for a netlist.

In accordance with a first aspect of the present disclosure, there is provided a computer-implemented method for selecting components for a netlist, comprising: generating a graph data structure, the components of the netlist and connections therebetween being represented by nodes and edges, respectively, in the graph data structure, wherein the edges between the nodes indicate types of the connections between the components; and processing the graph data structure to select one or more characteristics for each of the components.

In some or all examples of the first aspect, a node embedding can include a reference for each of the components in the graph data structure to a table of components.

In some or all examples of the first aspect, the table of components can have records for each component type.

In some or all examples of the first aspect, the one or more characteristics can include one or more of gain, bandwidth, and power.

In some or all examples of the first aspect, the processing can be performed using a relational graph convolution network (RGCN).

In some or all examples of the first aspect, the node embeddings can be processed by an actor model and a critic model.

In a second aspect of the present disclosure, there is provided a computing system for selecting components for a netlist, the computing system comprising: a processor; memory storing machine-executable instructions that, when executed by the processor, cause the processor to: generate a graph data structure, the components of the netlist and connections therebetween being represented by nodes and edges, respectively, in the graph data structure, wherein the edges between the nodes indicate types of the connections between the components; and process the graph data structure to select one or more characteristics for the components.

In some or all examples of the second aspect, a node embedding can include a reference for each of the components in the graph data structure to a table of components.

In some or all examples of the second aspect, the table of components can have records for each component type.

In some or all examples of the second aspect, the one or more characteristics can include one or more of gain, bandwidth, and power.

In some or all examples of the second aspect, the processing can be performed using a relational graph convolution network (RGCN).

In some or all examples of the second aspect, the node embeddings can be processed by an actor model and a critic model.

In a third aspect of the present disclosure, there is provided a non-transitory machine-readable medium having tangibly stored thereon executable instructions for execution by one or more processors, wherein the executable instructions, in response to execution by the one or more processors, cause the one or more processors to: generate a graph data structure, the components of the netlist and connections therebetween being represented by nodes and edges, respectively, in the graph data structure, wherein the edges between the nodes indicate types of the connections between the components; and process the graph data structure to select one or more characteristics for the components.

In some or all examples of the third aspect, a node embedding can include a reference for each of the components in the graph data structure to a table of components.

In some or all examples of the third aspect, the table of components can have records for each component type.

In some or all examples of the third aspect, the one or more characteristics can include one or more of gain, bandwidth, and power.

In some or all examples of the third aspect, the processing can be performed using a relational graph convolution network (RGCN).

In some or all examples of the third aspect, the node embeddings can be processed by an actor model and a critic model.

In a fourth aspect of the present disclosure, there is provided a computer-implemented method for selecting one or more characteristics for a netlist, comprising: generating a graph data structure, the components of the netlist and connections therebetween being represented by nodes and edges, respectively, in the graph data structure, wherein the edges between the nodes indicate types of the connections between the components; and processing the graph data structure to select one or more characteristics for the netlist.

In some or all examples of the fourth aspect, a node embedding can include a reference for each of the components in the graph data structure to a table of components.

In some or all examples of the fourth aspect, the table of components can have records for each component type.

In some or all examples of the fourth aspect, the one or more characteristics can include one or more of gain, bandwidth, power, and spacing of the components.

In some or all examples of the fourth aspect, the processing can be performed using a relational graph convolution network (RGCN).

In some or all examples of the fourth aspect, the node embeddings can be processed by an actor model and a critic model.

In a fifth aspect of the present disclosure, there is provided a computing system for selecting one or more characteristics for a netlist, the computing system comprising: a processor; memory storing machine-executable instructions that, when executed by the processor, cause the processor to: generate a graph data structure, the components of the netlist and connections therebetween being represented by nodes and edges, respectively, in the graph data structure, wherein the edges between the nodes indicate types of the connections between the components; and process the graph data structure to select one or more characteristics for the netlist.

In some or all examples of the fifth aspect, a node embedding can include a reference for each of the components in the graph data structure to a table of components.

In some or all examples of the fifth aspect, the table of components can have records for each component type.

In some or all examples of the fifth aspect, the one or more characteristics can include one or more of gain, bandwidth, power, and spacing of the components.

In some or all examples of the fifth aspect, the processing can be performed using a relational graph convolution network (RGCN).

In some or all examples of the fifth aspect, the node embeddings can be processed by an actor model and a critic model.

In a sixth aspect of the present disclosure, there is provided a non-transitory machine-readable medium having tangibly stored thereon executable instructions for execution by one or more processors, wherein the executable instructions, in response to execution by the one or more processors, cause the one or more processors to: generate a graph data structure, the components of the netlist and connections therebetween being represented by nodes and edges, respectively, in the graph data structure, wherein the edges between the nodes indicate types of the connections between the components; and process the graph data structure to select one or more characteristics for the netlist.

In some or all examples of the sixth aspect, a node embedding can include a reference for each of the components in the graph data structure to a table of components.

In some or all examples of the sixth aspect, the table of components can have records for each component type.

In some or all examples of the sixth aspect, the one or more characteristics can include one or more of gain, bandwidth, power, and spacing of the components.

In some or all examples of the sixth aspect, the processing can be performed using a relational graph convolution network (RGCN).

In some or all examples of the sixth aspect, the node embeddings can be processed by an actor model and a critic model.

Other aspects and features of the present disclosure will become apparent to those of ordinary skill in the art upon review of the following description of specific implementations of the application in conjunction with the accompanying figures.

### BRIEF DESCRIPTION OF THE DRAWINGS

FIGS. 1A and 1B are schematic diagrams of two different netlists.

FIG. 1C is a graph representation generated for either of the netlists of FIGS. 1A and 1B.

FIG. 2 is a schematic diagram of the general approach used to select component sizes for a netlist.

FIG. 3 shows elements of the approach of FIG. 2.

FIG. 4A is a schematic diagram of the netlist of FIG. 1A.

FIG. 4B is a schematic diagram of the netlist of FIG. 4A with additional attributes being identified.

FIG. 4C is a graph representation of the netlist of FIG. 4B with components being represented as nodes and different types of connections between the components being represented with different types of edges between the nodes.

FIG. 5 is a schematic diagram of the general process of modeling and selecting one or more characteristics for a netlist.

FIG. 6 is a flowchart of a general method of selecting components for a netlist in accordance with some example embodiments described herein.

FIG. 7 is a schematic diagram showing various physical and logical components of a computing system for selecting one or more characteristics for a netlist in accordance with some example embodiments described herein.

FIG. 8 shows performance results for the approach proposed herein in comparison to those using a current approach.

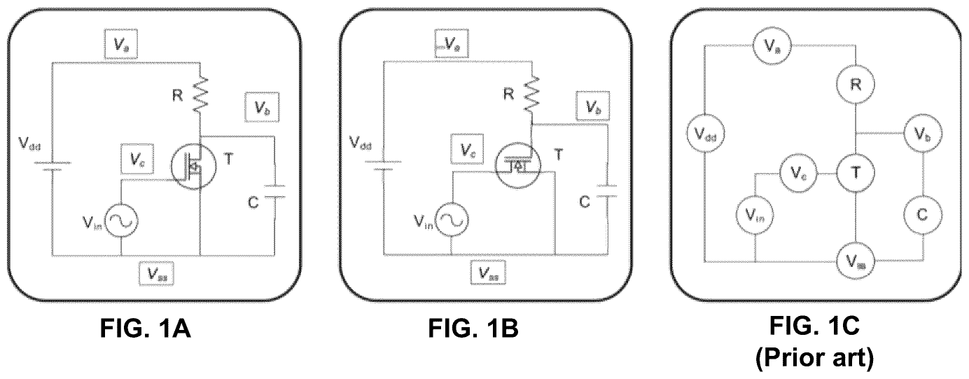

Unless otherwise specifically noted, articles depicted in the drawings are not necessarily drawn to scale.

### DETAILED DESCRIPTION OF EXAMPLE EMBODIMENTS

The present disclosure is made with reference to the accompanying drawings, in which embodiments are shown. However, many different embodiments may be used, and thus the description should not be construed as limited to the embodiments set forth herein. Rather, these embodiments are provided so that this application will be thorough and complete. Wherever possible, the same reference numbers are used in the drawings and the following description to refer to the same elements, and prime notation is used to indicate similar elements, operations or steps in alternative embodiments. Separate boxes or illustrated separation of functional elements of illustrated systems and devices does not necessarily require physical separation of such functions, as communication between such elements may occur by way of messaging, function calls, shared memory space, and so on, without any such physical separation. As such, functions need not be implemented in physically or logically separated platforms, although such functions are illustrated separately for ease of explanation herein. Different devices may have different designs, such that although some devices implement some functions in fixed function hardware, other devices may implement such functions in a programmable processor with code obtained from a machine-readable medium. Lastly, elements referred to in the singular may be plural and vice versa, except wherein indicated otherwise either explicitly or inherently by context.

One technical problem addressed by the approach disclosed herein is the inability of existing approaches to differentiate and generalize across netlists.

A new approach to selecting one or more characteristics for a netlist and enable better generalization with a more fine-grained way to encode and transfer the netlist information by considering different edge types between the components is disclosed herein. Embedding for different component types is learned. The additional information is used to enhance the generalization capacity across different netlists. This approach enables a reduction or elimination of the need for circuit design to be performed by humans.

Netlists are represented in a rich graph-based structure that encodes a netlist's information by considering different edge types between the components and keeping learnable embedding for component types. With this new approach to encoding the netlist, a downstream RL model can be learned with better generalization capacity. This facilitates knowledge transfer across different network topologies, and reduces or eliminates the need to employ circuit design experts.

The approach disclosed herein frames the problem of selecting one or more characteristics for a netlist (component sizing in particular, in some exemplary embodiments) as a reinforcement learning problem.

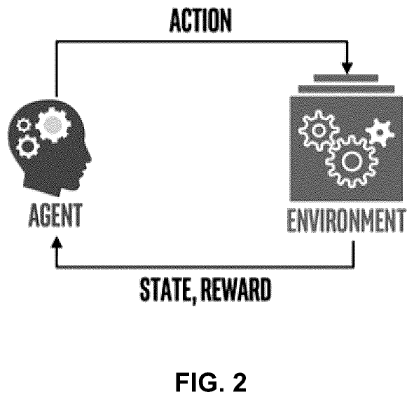

FIG. 2 shows a general workflow of an intelligent agent approach that can be used to select parameters for the components for the netlist. In artificial intelligence, an intelligent agent is anything which considers a task and takes actions autonomously in order to achieve goals related to that task. Actions in this scenario are generally vectors with values between 0 and 1 specifying a choice for each parameter. The state is the environment encoded as a graph. The intelligent agent can improve its performance using learned experience. In this approach, a unique manner for generating representations for netlists is provided. An agent uses an objective function that evaluates how well a solution meets the goals. A reward function enables the agent to learn how to react to changes in values of the objective function to more quickly arrive at a desirable solution. In particular, in this scenario, the reward is greater to or equal to zero if specifications for power, bandwidth, and gain are met, and less than zero if the specifications are not met.

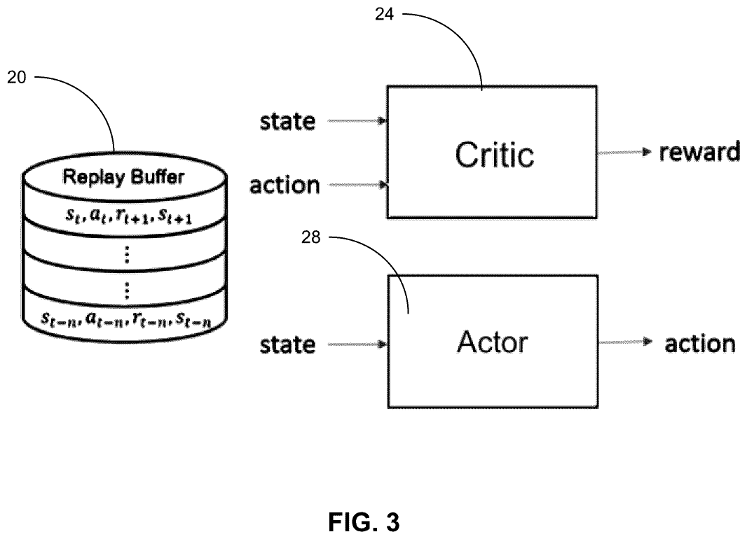

Shown in FIG. 3 are various components used to effect this approach. A replay buffer 20 stores interactions with the environment (state) and resulting rewards. A critic 24 learns to approximate the reward by training on the replay buffer using a state and action. An actor 28 learns actions which best improve the output of the critic based on a state.

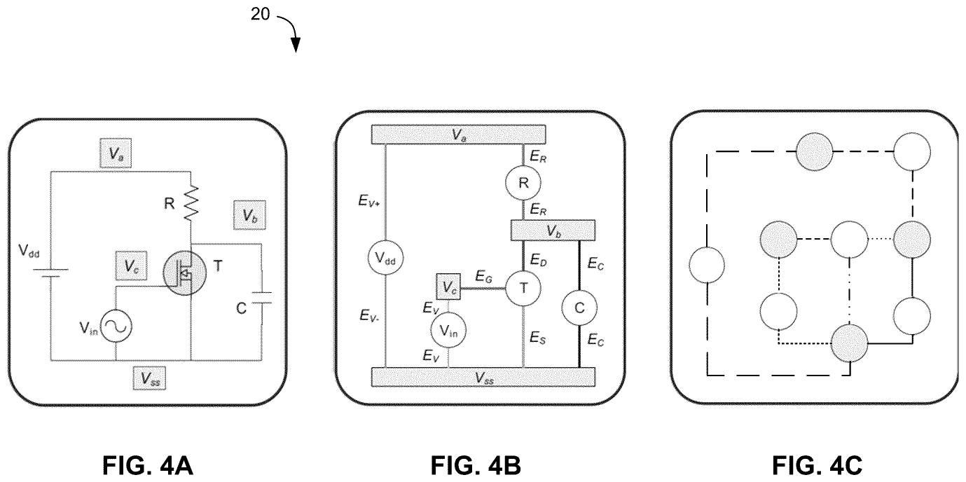

FIGS. 4A to 4C show an example of how a netlist is transformed into a heterogeneous graph. Specifically, the netlists are transformed into heterogeneous graphs using embedded references to a lookup table to learn representation for component types and adopt relational GCN (RGCN), as disclosed in “Modeling Relational Data with Graph Convolutional Networks”, arXiv: 1703.06103, to generate the final netlist embedding from the embedding lookup table and the graphs. FIG. 4A shows the original netlist. FIG. 4B shows the same netlist with additional names on the nets.

The following table shows representations for node and edge features for the actor and critic. The function e( ) denotes an embedding lookup operation, which maps each one-hot encoded feature to some learnable embedding.

| | |
|---|---|
| Node features for actor | Node features for critic |

| | | | |
|---|---|---|---|
| Net: | [e(10000)] | Net: | [e(10000), 00000] |
| Voltage: | [e(01000)] | Voltage: | [e(01000), 00000] |
| Resistor: | [e(00100)] | Resistor: | [e(00100), 000R0] |
| Capacitor: | [e(00010)] | Capacitor: | [e(00010), 0000C] |
| Transistor: | [e(00001)] | Transistor: | [e(00001), WLM00] |

The embeddings are references to positions or rows in a matrix. The data at the positions or in the rows provide component or connector types. In addition, in the above example list, the resistor, capacitor, and transistor have additional parameters specified directly; that is, 000R0, 0000C, and WLM00 respectively. The parameter for a transistor is (W; L; M), where W and L are the width and length of the transistor gate, M is the multiplexer. The parameter for a resistor is the resistance value R, and the parameter for a capacitor is the capacitance value C.

Node features are a combination of embeddings of component type and component-specific parameters. As shown in the above table, the actor only applies the learnable embedding of the component types. For the critic, the normalized component parameters are added to the representation.

Each connection between these nodes is represented by an undirected edge. The edge type is uniquely determined by the component type and terminal type it connects to. For the symmetric components (e.g., resistor, capacitor), the terminals are treated as the same type. For the non-symmetric components (e.g., transistor, power source), different terminal types are assigned to them.

FIG. 4C shows the final heterogeneous graph derived from the netlist of FIG. 4A. The different line types of the edges denote different edge types. Components in the circuit (resistor R, transistor T, capacitor C, etc.) and the nets (0, Vd, VDD, Vg) connecting each of these components are represented as nodes.

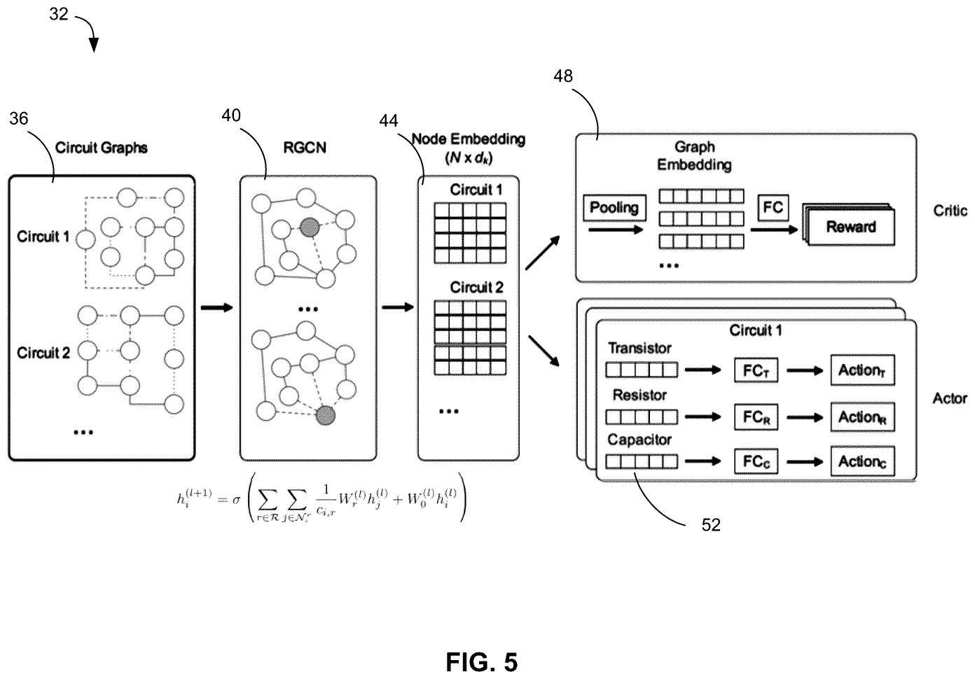

FIG. 5 shows the overall workflow 32 of the DDPG approach for solving the component selection problem using the enhanced graph data structure(s) 36 described herein to represent the netlist. An RGCN model 40 is generated from the enhanced data structure. As a learning-based approach is employed, the raw netlist is transformed into some embedding 44, which is a real-valued vector, so that the information from the netlist can be rapidly utilized by the downstream learning model. The representation is fed to a critic model 48 and an actor model 52 of the DDPG framework. The critic model 52 uses the component and connection embeddings to approximate the reward model. The actor model 52 uses the reward model to predict the appropriate parameter values that can best improve the circuit being designed. The other settings are the same as disclosed in “GCN-RL Circuit Designer: Transferable Transistor Sizing with Graph Neural Networks and Reinforcement Learning”, arXiv:2005.00406.

The RGCN layer 40 ensures that independent component parameters are learned for each type of edge to better encode the netlist information. Specifically, let xx denote the node embedding of node I at layer k. The RGCN layer is defined as:

$${x}_{i}^{k} = {θ}_{0}^{k} \cdot {x}_{i}^{k - 1} + {\sum }_{r ∈ R} {\sum }_{j ∈ {N}_{r} ( i )} \frac{1}{\vert {N}_{r} ( i ) \vert} {θ}_{r}^{k} \cdot {x}_{j}^{k - 1} ,$$

where θᵣ^{k} denotes the learnable parameters, and Nᵣ(i) denotes the node neighbor of node i of type r. Thus, xᵢ⁰ represents the node features.

When the component sizing problem for multiple circuits is solved simultaneously, the netlist coder with a heterogenous graph model and the embedding for component types are better tailored to the representation of netlists. This brings about a larger representation capacity and can the learned model parameters can better generalize to different netlists.

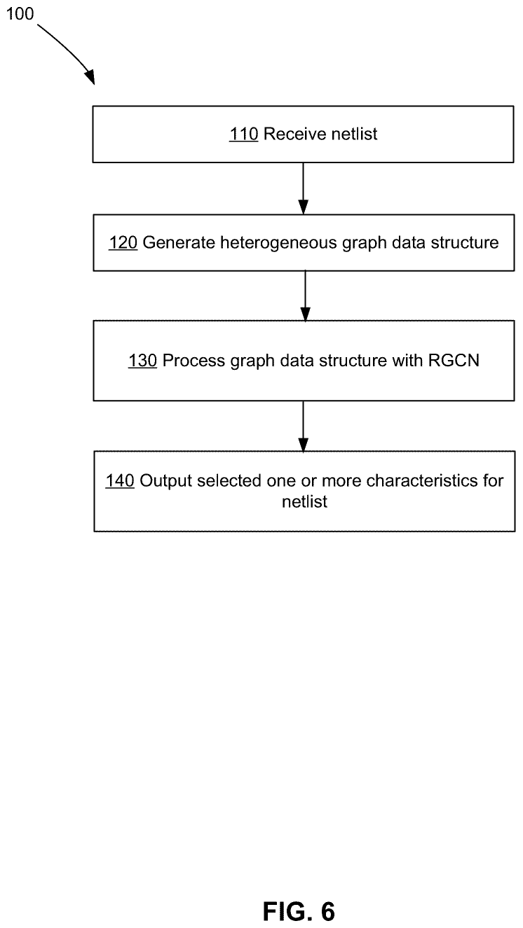

Now with reference to FIG. 6, a method 100 for selecting components for a netlist is shown. The method 100 commences with the receipt of a netlist (110). Then a heterogeneous graph data structure is generated from the netlist (120). As noted above, the components are represented by nodes and the connections between the components are represented by edges between the nodes. Each of the edges between the nodes are richly represented as a certain edge type that is uniquely determined by the component type and terminal type it connects to. Upon generation of the heterogeneous graph data structure at 120, the graph data structure is processed by a RGCN to select one or more characteristics for the netlist (130). The RGCN in some embodiments selects component sizes, but in other embodiments, can select other characteristics for the netlist. Upon processing the graph data structure with the RGCN to select the one or more characteristics for the netlist, the selection(s) are outputted (140). The output can be stored in memory of computer system, presented on a display, communicated to another computer system via a network, etc.

The proposed approach is not limited to the domain of finding optimal component sizes in an analog circuit. It can also be used in related problems for determining one or more characteristics for a netlist. Examples of such problems include analog IC placement, layout parasitic estimation, identifying symmetries, identifying subcircuits, etc., where a representation of learning techniques for encoding the netlists is used.

The steps (also referred to as operations) in the flowcharts and drawings described herein are for purposes of example only. There may be many variations to these steps/operations without departing from the teachings of the present disclosure. For instance, the steps may be performed in a differing order, or steps may be added, deleted, or modified, as appropriate.

In other embodiments, the same approach described herein can be employed for other modalities.

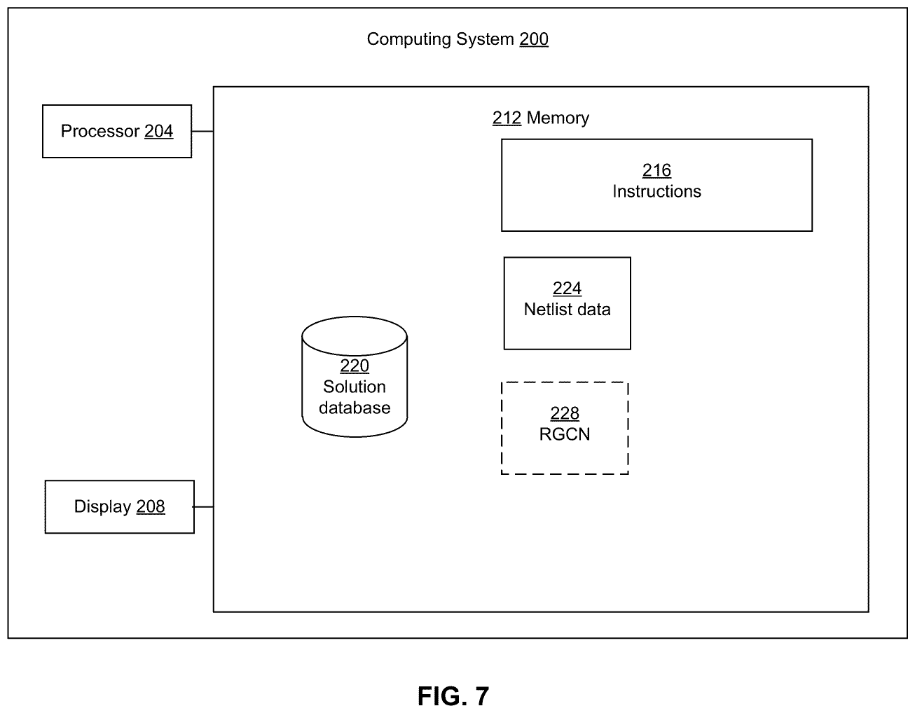

FIG. 7 shows various physical and logical components of an exemplary computing system 200 for selecting components for a netlist in accordance with example embodiments of the present disclosure. Although an example embodiment of the computing system 200 is shown and discussed below, other embodiments may be used to implement examples disclosed herein, which may include components different from those shown. Although FIG. 3 shows a single instance of each component of the computing system 200, there may be multiple instances of each component shown. The example computing system 200 may be part of, or connected to, a device for selecting components for a netlist, analog IC placement, layout parasitic estimation, identifying symmetries, identifying subcircuits, etc.

The computing system 200 includes one or more processors 204, such as a central processing unit, a microprocessor, an application-specific integrated circuit (ASIC), a field-programmable gate array (FPGA), a dedicated logic circuitry, a tensor processing unit, a neural processing unit, a dedicated artificial intelligence processing unit, or combinations thereof. The one or more processors 204 may collectively be referred to as a processor 204. The computing system 200 may include a display 208 for outputting data and/or information in some applications, but may not in some other applications.

The computing system 200 includes one or more memories 212 (collectively referred to as “memory 212”), which may include a volatile or non-volatile memory (e.g., a flash memory, a random access memory (RAM), and/or a read-only memory (ROM)). The non-transitory memory 212 may store machine-executable instructions for execution by the processor 204. A set of machine-executable instructions 216 defining an application process for selecting components for a netlist (described herein) is shown stored in the memory 212, which may be executed by the processor 204 to perform the steps of the methods for selecting components for a netlist described herein. The memory 212 may include other machine-executable instructions for execution by the processor 204, such as machine-executable instructions for implementing an operating system and other applications or functions.

In some examples, the computing system 200 may also include one or more electronic storage units (not shown), such as a solid state drive, a hard disk drive, a magnetic disk drive and/or an optical disk drive. In some examples, one or more datasets and/or modules may be provided by an external memory (e.g., an external drive in wired or wireless communication with the computing system 200) or may be provided by a transitory or non-transitory computer-readable medium. Examples of non-transitory computer readable media include a RAM, a ROM, an erasable programmable ROM (EPROM), an electrically erasable programmable ROM (EEPROM), a flash memory, a CD-ROM, or other portable memory storage. The storage units and/or external memory may be used in conjunction with memory 212 to implement data storage, retrieval, and caching functions of the computing system 200.

The memory 212 stores the replay buffer 20 that includes state, action, and reward sets, and the netlist data 220. In addition, the machine-executable instructions 216, when executed by the processor 204, instantiate the RGCN model 40 in memory 212.

The components of the computing system 200 may communicate with each other via a bus, for example. In some embodiments, the computing system 200 is a distributed computing system and may include multiple computing devices in communication with each other over a network, as well as optionally one or more additional components. The various operations described herein may be performed by different computing devices of a distributed system in some embodiments. In some embodiments, the computing system 200 is a virtual machine provided by a cloud computing platform.

Although the components for selecting components for a netlist are shown as part of the computing system 200, it will be understood that separate computing devices can be used for selecting components for a netlist.

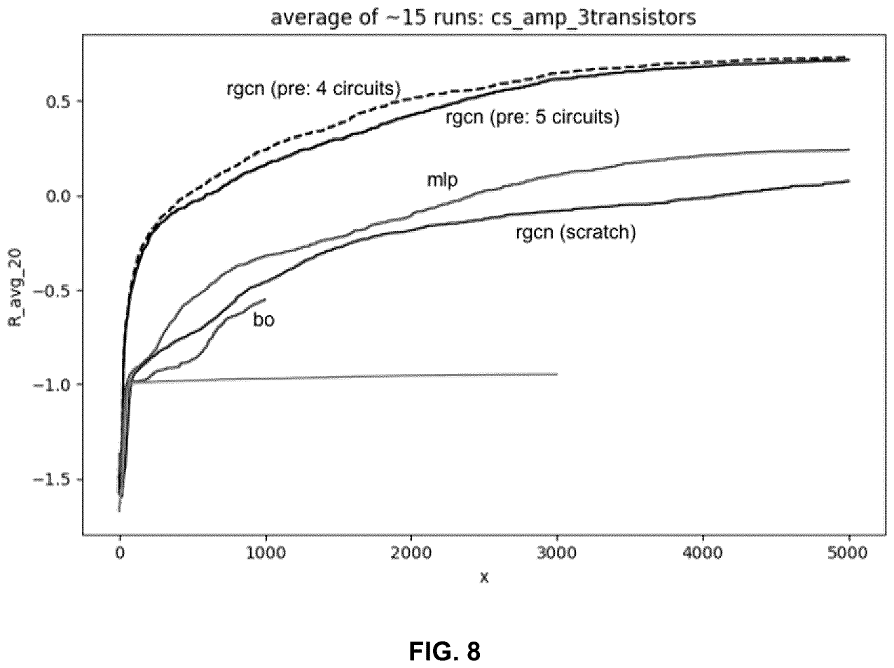

FIG. 8 shows the performance of a system using the general approach disclosed herein compared to the performance of current state-of-the-art systems results. As can be seen, the general approach disclosed herein provides significant improvements over current state-of-the-art systems.

The novel framework for selecting components for a netlist presented herein outperforms the current state-of-the-art frameworks for selecting components for a netlist. The fundamental idea behind the disclosed approach is the use of a heterogeneous graph data structure to represent the components of a netlist and connections therebetween. Further, by referencing a table of components and/or connections in the graph data structure for the netlist, solutions can be generalized.

### General

Through the descriptions of the preceding embodiments, the present invention may be implemented by using hardware only, or by using software and a necessary universal hardware platform, or by a combination of hardware and software. The coding of software for carrying out the above-described methods described is within the scope of a person of ordinary skill in the art having regard to the present disclosure. Based on such understandings, the technical solution of the present invention may be embodied in the form of a software product. The software product may be stored in a non-volatile or non-transitory storage medium, which can be an optical storage medium, flash drive or hard disk. The software product includes a number of instructions that enable a computing device (personal computer, server, or network device) to execute the methods provided in the embodiments of the present disclosure.

All values and sub-ranges within disclosed ranges are also disclosed. Also, although the systems, devices and processes disclosed and shown herein may comprise a specific plurality of elements, the systems, devices and assemblies may be modified to comprise additional or fewer of such elements. Although several example embodiments are described herein, modifications, adaptations, and other implementations are possible. For example, substitutions, additions, or modifications may be made to the elements illustrated in the drawings, and the example methods described herein may be modified by substituting, reordering, or adding steps to the disclosed methods.

Features from one or more of the above-described embodiments may be selected to create alternate embodiments comprised of a sub-combination of features which may not be explicitly described above. In addition, features from one or more of the above-described embodiments may be selected and combined to create alternate embodiments comprised of a combination of features which may not be explicitly described above. Features suitable for such combinations and sub-combinations would be readily apparent to persons skilled in the art upon review of the present disclosure as a whole.

In addition, numerous specific details are set forth to provide a thorough understanding of the example embodiments described herein. It will, however, be understood by those of ordinary skill in the art that the example embodiments described herein may be practiced without these specific details. Furthermore, well-known methods, procedures, and elements have not been described in detail so as not to obscure the example embodiments described herein. The subject matter described herein and in the recited claims intends to cover and embrace all suitable changes in technology.

Although the present invention and its advantages have been described in detail, it should be understood that various changes, substitutions and alterations can be made herein without departing from the invention as defined by the appended claims.

The present invention may be embodied in other specific forms without departing from the subject matter of the claims. The described example embodiments are to be considered in all respects as being only illustrative and not restrictive. The present disclosure intends to cover and embrace all suitable changes in technology. The scope of the present disclosure is, therefore, described by the appended claims rather than by the foregoing description. The scope of the claims should not be limited by the embodiments set forth in the examples, but should be given the broadest interpretation consistent with the description as a whole.

1. A computer-implemented method for selecting components for a netlist, comprising:
generating a graph data structure, the components of the netlist and connections therebetween being represented by nodes and edges, respectively, in the graph data structure, wherein the edges between the nodes indicate types of the connections between the components; and
processing the graph data structure to select one or more characteristics for the components.

2. The computer-implemented method of claim 1, wherein a node embedding includes a reference for each of the components in the graph data structure to a table of components.

3. The computer-implemented method of claim 2, wherein the table of components has records for each component type.

4. The computer-implemented method of claim 3, wherein the one or more characteristics include one or more of gain, bandwidth, and power.

5. The computer-implemented method of claim 2, wherein the processing is performed using a relational graph convolution network (RGCN).

6. The computer-implemented method of claim 3, wherein the processing is performed using a relational graph convolution network (RGCN).

7. The computer-implemented method of claim 6, wherein the node embeddings are processed by an actor model and a critic model.

8. A computing system for selecting components for a netlist, the computing system comprising:
a processor;
memory storing machine-executable instructions that, when executed by the processor, cause the processor to:
generate a graph data structure, the components of the netlist and connections therebetween being represented by nodes and edges, respectively, in the graph data structure, wherein the edges between the nodes indicate types of the connections between the components; and
process the graph data structure to select one or more characteristics for the components.

9. The computing system of claim 8, wherein a node embedding includes a reference for each of the components in the graph data structure to a table of components.

10. The computing system of claim 9, wherein the table of components has records for each component type.

11. The computing system of claim 10, wherein the one or more characteristics include one or more of gain, bandwidth, and power.

12. The computing system of claim 9, wherein the processing is performed using a relational graph convolution network (RGCN).

13. The computing system of claim 10, wherein the processing is performed using a relational graph convolution network (RGCN).

14. The computing system of claim 13, wherein the node embeddings are processed by an actor model and a critic model.

15. A non-transitory machine-readable medium having tangibly stored thereon executable instructions for execution by one or more processors, wherein the executable instructions, in response to execution by the one or more processors, cause the one or more processors to:
generate a graph data structure, the components of the netlist and connections therebetween being represented by nodes and edges, respectively, in the graph data structure, wherein the edges between the nodes indicate types of the connections between the components; and
process the graph data structure to select one or more characteristics for the netlist.

16. The non-transitory machine-readable medium of claim 15, wherein a node embedding includes a reference for each of the components in the graph data structure to a table of components.

17. The non-transitory machine-readable medium of claim 16, wherein the table of components has records for each component type.

18. The non-transitory machine-readable medium of claim 17, wherein the one or more characteristics include one or more of gain, bandwidth, and power.

19. The non-transitory machine-readable medium of claim 16, wherein the processing is performed using a relational graph convolution network (RGCN).

20. The non-transitory machine-readable medium of claim 17, wherein the processing is performed using a relational graph convolution network (RGCN).
